(19) United States
(12) Patent Application Publication
(10) Pub. No.: US 2025/0167168 A1
(43) Pub. Date: May 22, 2025

(54) ELECTRONIC PACKAGE WITH INTEGRATED ANTENNAS AND A METHOD FOR FORMING THE SAME

(71) Applicant: JCET STATS ChipPAC Korea Limited, Incheon (KR)

(72) Inventors: SeungHyun LEE, Incheon (KR); HunTaek LEE, Gyeonggi-do (KR); HeeSoo LEE, Incheon (KR)

(21) Appl. No.: 18/945,569

(22) Filed: Nov. 13, 2024

(30) Foreign Application Priority Data
Nov. 17, 2023 (CN) 202311602107.9

(51) Int. Cl. H01L 23/00; H01L 21/48; H01L 21/56; H01L 25/00; H01Q 1/22

(52) U.S. Cl. CPC H01L 24/81; H01L 21/4846; H01L 21/56; H01L 24/97; H01L 25/50; H01Q 1/2283; H01L 2224/81201; H01L 2224/81947; H01L 2224/95001

(57) ABSTRACT

A method for forming an electronic package is provided. The method comprises: providing a package substrate having a front surface and a back surface, wherein multiple sets of conductive pads are formed on the front surface of the package substrate; forming solder bumps on each set of conductive pads; attaching multiple front electronic components onto the front surface of the package substrate via solder bumps, wherein each of the multiple front electronic components is aligned with one set of the multiple sets of conductive pads; loading the package substrate on a bottom chase with the front surface facing upward; pressing, with a top chase, the front electronic components against the bottom chase to reshape the solder bumps and horizontally align top surfaces of the front electronic components with each other; and forming a front mold cap on the front surface to encapsulate the front electronic components.

### TECHNICAL FIELD

The present application generally relates to semiconductor packaging technology, and more particularly, to an electronic package with integrated antennas and a method for forming the same.

### BACKGROUND OF THE INVENTION

The semiconductor industry is constantly faced with complex integration challenges as consumers want their electronics to be smaller, faster and higher performance with more and more functionalities packed into a single device. In recent years, there is increasing need for multi-functional electronic packages with high speed and stability, such as Antenna-in-Package (AiP) devices. Particularly, in some electronic package assemblies, multiple electronic components such as antennas are fabricated separately and then be assembled together on a single substrate. However, the mentioned-above fabrication process may adversely affect the uniformity of the electronic package incorporating such electronic components and may also cause a decreased performance.

Therefore, a need exists for a method for forming an electronic package with multiple electronic components that can be more uniformly mounted in the package.

### SUMMARY OF THE INVENTION

An objective of the present application is to provide a method for forming an electronic package with multiple electronic components that can be more uniformly mounted in the package.

According to an aspect of the present application, an electronic package and a method for forming the same is provided. The method comprises: providing a package substrate having a front surface and a back surface, wherein multiple sets of conductive pads are formed on the front surface of the package substrate; forming solder bumps on each set of the multiple sets of conductive pads; attaching multiple front electronic components onto the front surface of the package substrate via solder bumps, wherein each of the multiple front electronic components is aligned with one set of the multiple sets of conductive pads; loading the package substrate on a bottom chase with the front surface of the package substrate facing upward; pressing, with a top chase, the front electronic components against the bottom chase to reshape the solder bumps and horizontally align top surfaces of the front electronic components with each other; and forming a front mold cap on the front surface of the package substrate to encapsulate the front electronic components.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1F illustrate various steps of a method for forming an electronic package according to a first embodiment of the present application.

FIGS. 2A and 2B illustrate a portion of various steps of a method for forming an electronic package according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, in some electronic devices such as Antenna-in-Package (AiP) devices, multiple electronic components such as antennas, which may have an identical structure and form, are fabricated separately and then be assembled together on a package substrate of the device to achieve a desired performance and functionality. The inventors of the present application noticed that electronic packages incorporating such electronic components have a worse uniformity in assembling and thus a decreased performance. After an investigation of many samples of the electronic package, the inventors have identified that there may be a significant height difference between two or more of the electronic components on the same package substrate, due to a difference in the size and height of solder bumps that mount the electronic components on the package substrate. To address this issue, a new method for mounting the electronic components on a substrate is provided, which introduces a pressing step to obtain solder bumps with a substantially uniform height. The method can be used in forming an electronic package such as an AiP package, as a portion of the steps of the forming process.

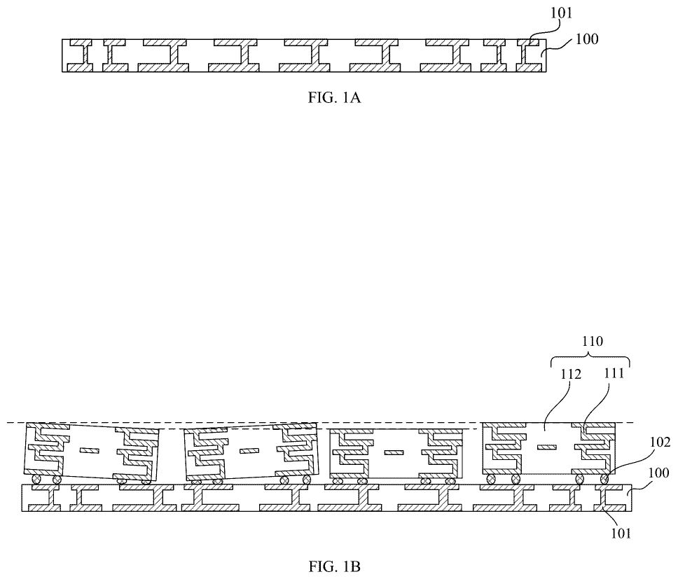

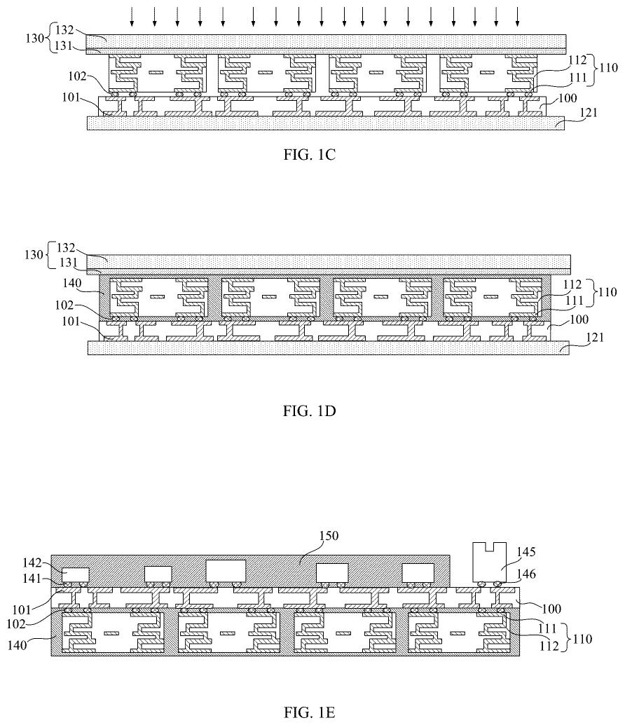

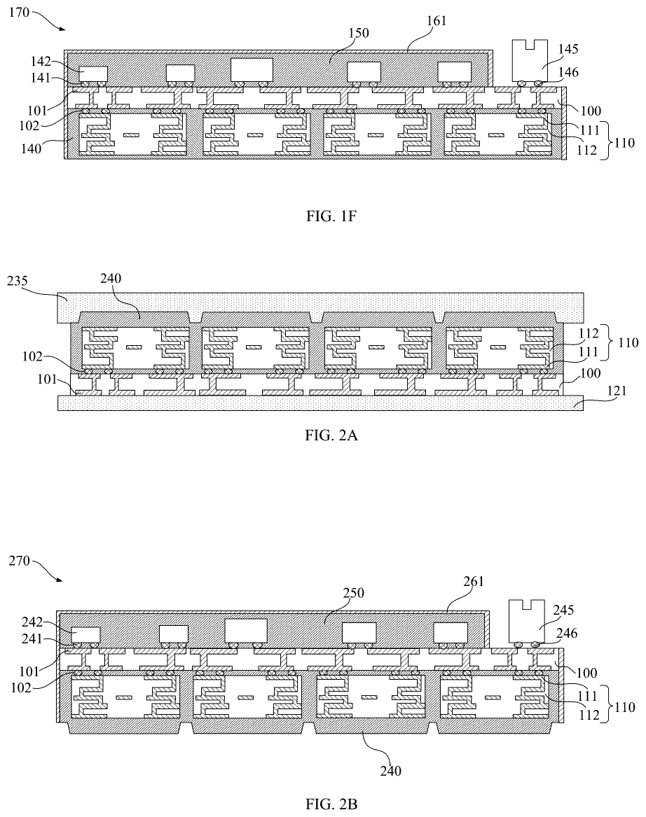

FIGS. 1A to 1F illustrate various steps of a method for forming an electronic package according to a first embodiment of the present application. In the following, the method will be described with reference to FIGS. 1A to 1F in more details.

As shown in FIG. 1A, a package substrate 100 is provided with embedded interconnect wires 101. The package substrate 100 includes a front surface and a back surface, which are opposite to each other. The front surface of the package substrate 100 may serve as a platform where electronic components can be mounted. In some embodiments, the electronic package may be a double side molded (DSM) package, and accordingly, the back surface may also serve as another platform where electronic component(s) may be mounted. Multiple sets of conductive pads (not shown) can be formed on the front surface and/or back surface of the package substrate 100 for the mounting of the electronic components. It can be appreciated that the multiple sets of conductive pads may be exposed portions of interconnect wires 101 formed within the package substrate 100.

As shown in FIG. 1B, a solder material is deposited onto the front surface of the package substrate 100 to form a plurality of solder bumps 102 on each set of the multiple sets of conductive pads. The solder bump material can be Al, Sn, Ni, Au, Ag, lead (Pb), bismuth (Bi), Cu, or combinations thereof, with an optional flux solution. In some embodiments, the solder material is deposited by a method of solder paste printing or flux printing.

Next, multiple front electronic components 110 are attached onto the front surface of the package substrate 100 via the solder bumps 102, thus forming electrical connection between the interconnect wires 101 and the front electronic components 110. In the embodiment shown in FIG. 1B, the front electronic components 110 include antenna blocks with a same height. Preferably, the antenna blocks may be of the same structure and form, for example, be fabricated using the same process and singulated from an antenna substrate strip. To be more specific, each antenna block further includes one or more antennas 111 and a dielectric layer 112 surrounding the antennas 111. In some embodiments, the number of the antennas 111 included in each antenna block may vary according to actual needs of the electronic package. In addition, the dielectric layer 112 may include materials such as an insulative polymeric material or composite. In this example, bottom surfaces of the antennas 111 are exposed from a bottom surface of the dielectric layer 112 for contacting the solder bumps 102. In some embodiments, multiple conductive pads can be formed on the bottom surface of the antenna blocks 110, i.e., on the bottom surface of the antennas 111, for the mounting of the antenna blocks 110 on to the package substrate 100 through the respective solder bumps 102. In some embodiments, top surfaces of the antennas 111 may be exposed from a top surface of the dielectric layer 112. It can also be appreciated that the dielectric layer 112 may cover the top surfaces of the antennas 111 in some alternative embodiments. In some other embodiments, the front electronic components 110 may include blocks incorporating other types of electronic modules such as semiconductor chips, resistors, capacitors or the like. At least some of the front electronic components 110 have the same form, or especially the same height.

Furthermore, the front electronic components 110 may be mounted on the front surface at different positions. Each of the multiple front electronic components 110 is aligned with one set of the multiple sets of conductive pads on the front surface of the package substrate 100. In this example, the front electronic components 110 are positioned evenly on the front surface of the package substrate 100. However, it can be appreciated that the front electronic components 110 may be attached onto the front surface of the package substrate 100 with a different distance and arrangement. Also, the number of the front electronic components 110 attached onto the front surface may be vary, depending on the actual needs of the electronic package.

Still referring to FIG. 1B, although the front electronic components 110 may be antenna blocks with the same height, the front electronic components 110 at different positions on the package substrate 100 may have different heights or may even be tilted with relative to the front surface of the package substrate 100. The different heights or tilting may result from the unevenness of the front surface of the package substrate 100, the nonuniformity of the forming process of the solder bumps 102 and the inconformity of the attaching process of the front electronic components 110 onto the package substrate 100. For example, the heights of the solder bumps 102 under some of the front electronic components 110 may be different from the heights of the solder bumps 102 under the front electronic components 110 at other positions of the front surface, rendering a height difference between the top surfaces of the front electronic components 110. Furthermore, the front electronic components 110, for example, the antenna blocks incorporating multiple antennas in this case, may extend a sufficient dimension in a lengthwise direction or widthwise direction. The unevenness of the front surface and the height differences of the solder bumps 102 under the single front electronic component 110 may result in an angle between the top surfaces of the front electronic component 110 and the front surface of the package substrate 100, thus causing the front electronic components 110 tilt to some extent. A pressing process may be conducted to address this issue.

As shown in FIG. 1C, the package substrate 100 is loaded on a bottom chase 121 with the front surface of the package substrate 100 facing upward. The bottom chase 121 may be used for placing the package substrate 100 and providing upward supporting forces when the front electronic components 110 are pressed against the bottom chase 121. In a preferred embodiment, a length of the bottom chase 121 in a horizontal direction may be greater than that of the package substrate 100 to provide sufficient and balanced forces to support the package substrate 100.

Next, the front electronic component 110 are pressed against the bottom chase 121 with a top chase 130 to reshape the solder bumps 102. In this example, all of the multiple front electronic components 110 are in contact with the same surface of the top chase 130 to receive forces simultaneously from the top chase 130. During the pressing process, the solder bumps 102 may be substantially flattened, for example, from a circular shape to an oval shape or even a disk shape, thereby resulting in reduced distances from the top surfaces of the front electronic components 110 to the front surface of package substrate 100 in a controlled way. After the pressing step, the top surfaces of the multiple front electronic components 110 are horizontally aligned with each other, which allows for enhanced uniformity of the structures of the front electronic components 110. Especially for AiP devices, the antenna blocks that are uniformly mounted on the substrate of the AiP device can improve signal receiving and transmission performance because these antenna blocks can be oriented accurately. It can be appreciated that, the amount of reduction in the height of the solder bumps 102 may be different, depending on the original heights of the solder bumps 102. The higher the original height is, the more compression or reduction in height is. Also, since the front electronic components 110, especially the antenna blocks in this embodiment, may have a stiffness greater than that of the solder bumps 102, the pressing process may not reshape the front electronic components 110.

In the embodiment shown in FIG. 1C, the top chase 130 may include a base plate 132 and a flexible film 131, and the flexible film 131 is in contact with the top surfaces of the multiple front electronic components 110 during the pressing step. The flexible film 131 may serve as a release film, which provides a buffer between the base plate 132 and the front electronic components 110 to protect the front electronic components 110 from potential damage during the pressing step. The material of the flexible film 131 may include foamed plastic, rubber or the like. In some embodiments, the flexible film 131 can be a multi-layer structure which provides a more delicate buffer between the base plate 132 and the front electronic components 110. In some other embodiments, the flexible material can be omitted, where the base plate 132 may directly contact the surfaces of the multiple front electronic components 110.

It can be appreciated that since the pressing step may reduce the heights of the solder bumps 102, respective cross sections of the solder bumps 102 in the horizontal direction may expand for some extent. However, the pressing step may be implemented that the solder bumps 102 underneath each of the front electronic components 110 are reshaped but not connected with each other, to avoid potential short-circuit risks. Therefore, during the pressing step, the pressure and forces applied onto the top chase 130 should be determined based on the space and distance between adjacent solder bumps 102. In some embodiments, a stopper may be provided between the top and bottom chases 130, 121 to limit a maximum distance the top chase 130 can move toward the bottom chase 121.

It can also be appreciated that the pressing step may be implemented when a reflowing of the solder bumps 102 is being implemented. Also, the solder bumps 102 may exhibit deformable characteristics which may be reshaped by external forces.

In some optional embodiments, after the pressing step, multiple additional front electronic components (not shown) may be attached onto the front surface of the package substrate via additional solder bumps. The additional front electronic components may incorporate other types of electronic modules, for example, semiconductor chips, resistors, capacitors or the like, which are different from the electronic modules incorporated in the front electronic components 110. However, in some other embodiments, the additional front electronic components may include the same type of electronic modules as the front electronic components 110 that have been mounted on the package substrate 100. In particular, the additional front electronic components are thicker than the front electronic components 110 attached onto the front surface of the package substrate 100, and each of the additional front electronic components is aligned with one set of the multiple sets of conductive pads. The additional front electronic components may have the same structure and form, or especially the same height. As such, a similar pressing process may be conducted to the additional front electronic components to ensure uniformity of these components on the package substrate 100. In particular, the package substrate 100 can be loaded on the bottom chase 121 again with the front surface of the package substrate 100 facing upward. The additional front electronic components are pressed with the top chase 130 or another top chase against the bottom chase 121 to reshape the additional solder bumps and horizontally align top surfaces of the multiple additional electronic components with each other. In this way, the top surfaces of the multiple additional electronic components are horizontally aligned with each other, which improves overall uniformity of the various electronic components attached on the front surface. Since the additional front electronic components are higher than the front electronic components 110 that have been mounted on the package substrate 100, the pressing process to these additional front electronic components may not affect the front electronic components 110 that have been mounted on the package substrate 100.

Next, as shown in FIG. 1D, a molding material is formed between the top chase 130 and the front surface of the package substrate 100 to form a front mold cap 140 which encapsulates the front electronic components 110. In some embodiments, the top chase 130 is lifted up above the top surfaces of the front electronic components 110 before the molding material is formed, so that the lateral surfaces and top surfaces of the front electronic components 110 may be covered by the front mold cap 140 for encapsulation. The front mold cap 140 is formed using a molding process such as a film-assisted molding (FAM) process. During this process, the molding material is first liquefied by heat and pressure, and then forced into a closed mold cavity (e.g., the cavity in the top chase) and held there under additional heat and pressure until all material is solidified. The FAM process enables easy release of the encapsulated package from the chases since the molding material contacts the assisting film instead of the metal mold chase. Also, the assisting film may function as a soft cushion, resulting in less wear of mold parts. The mold material used in the FAM process may include very sticky type and liquid silicone materials, for example. It can be appreciated that the assisting film may include the flexible film 131 of the top chase 130 when the top chase 130 is used for both pressing and molding, such as that illustrated in this embodiment. In some other embodiments, the front mold cap 140 can also be formed using other molding technologies. Moreover, the bottom surface of the top chase 130 is an extended flat surface, which results in a flat top surface of the formed front mold cap. In some other embodiments, the front mold cap is formed using a molding top chase which includes multiple cavities each corresponding to one of the front electronic components 110, which will be elaborated below.

As shown in FIG. 1E, the package substrate 100 and the various components thereon may be removed from the top chase 130 and the bottom chase 121. The package substrate 100 may then be flipped over for further attachment of other components on its back surface. In particular, at least one back electronic component 142 is attached onto the back surface of the package substrate 100. The back electronic components 142 may be electrically connected with interconnect wires 101 embedded in the package substrate 100 via a plurality of solder bumps 141. In this way, the back electronic components 142 mounted on the back surface and the front electronic components 110 mounted on the front surface can be electrically connected with each other, forming an integrated electronic package.

In some embodiments, the back electronic components 142 may include various types of electronic modules, such as semiconductor chips, resistors, capacitors or the like. The back electronic components 142 may have different sizes. In the embodiment shown in FIG. 1E, at least one auxiliary back electronic component 145 may be mounted onto the back surface of the package substrate 100 via additional solder bumps 146. The auxiliary back electronic components 145 may include a type of electronic module different from that of the back electronic components 142. For example, the auxiliary back electronic components 145 may include a connector such as a board-to-board (B2B) connector in this embodiment. The connector 145 is used for electrically coupling the electronic package with other electronic devices external to the electronic package. In addition, a height of the auxiliary back electronic components 145 may also be different from that of the back electronic components 142. In some other embodiments, it can be appreciated that the back electronic components 142 and the auxiliary back electronic component 145 may be arranged and sized according to actual needs of the semiconductor package.

Next, still referring to FIG. 1E, a molding material is formed on at least part of the back surface of the package substrate 100 to form a back mold cap 150 that encapsulates the at least one back electronic component 142 on the back surface. Similar as the molding process for the front mold cap 140 illustrated in FIG. 1D, the back mold cap 150 may be formed using a molding process such as an injection molding process, which covers respective top and lateral surfaces of the back electronic components 142 for encapsulation. In this case, the auxiliary back electronic component 145, the connector in this embodiment, and the back surface underneath the connector 145 may be exposed from the back mold cap 150 to allow for proper electrical connection between the connector 145 and the external electronic devices. It can be appreciated that the electronic components on the back surface which need to be encapsulated by the back mold cap 150 may vary according to actual needs of the electronic package.

Therefore, a double side molded package is formed with the electronic components attached and packaged on both the front surface and the back surface of the package substrate 100. In some embodiments, the solder bumps 141, 146 may be reflowed before the back mold cap 150 is formed.

As shown in FIG. 1F, a shielding layer 161 is formed at least outside the top and lateral surfaces of the back mold cap 150, thus forming an electronic package 170. The shielding layer 161 may help to protect the other parts of the electronic package 170 from electromagnetic interferences. In some embodiments, the shielding layer 161 may extend to other structures adjacent to the back mold cap 150, such as the package substrate 100 and the front mold cap 140, for example. In some embodiments, the package substrate 100 may be singulated into smaller units before or after the formation of the shielding layer 161. The auxiliary back electronic component 145, which is the connector in the embodiment shown in FIG. 1F, is free from the shielding layer 161, allowing for proper electrical connection between the connector 145 and external electronic devices.

In some embodiments, the electronic package 170 can be applied in any electronic devices which desire front electronic components 110 with uniform structures and improved performance, such as in high-sensitive sensors, high performance radio frequency devices or the like. Furthermore, although it is shown in the embodiment shown in FIGS. 1A to 1F that both the front surface and the back surface of the package substrate 100 are mounted with certain electronic components, in some other embodiments, only the front surface of the package substrate 100 is mounted with the electronic components. For example, the antenna blocks 110 may be mounted on the front surface which may be desired to be pressed to obtain a uniform height, and some other electronic components may be mounted before the antenna blocks 110. It can be appreciated similar pressing process may be performed to the antenna blocks 110.

In the embodiment shown in FIGS. 1A to 1F, the bottom surface of the top chase 130 is an extended flat surface. The front mold cap 140 is formed using the top chase 130 and the bottom chase 121 when the package substrate 100 is loaded between the top chase 130 and the bottom chase 121, thus forming the front mold cap 140 with a flat top surface. In some other embodiments, the front mold cap may be formed using a molding top chase which includes multiple cavities each corresponding to one of the front electronic components 110. Thus the front mold cap may have multiples stages at its top surfaces, and each stage may be aligned with one of the multiple front electronic components 110, which will be elaborated below.

FIGS. 2A and 2B illustrate a portion of various steps of a method for forming an electronic package according to a second embodiment of the present application. The steps illustrated in FIGS. 2A and 2B may be implemented on a package substrate 100 after the steps illustrated in FIGS. 1A to 1C have been performed, instead of the steps illustrated in FIGS. 1D to 1F, as an alternative embodiment to the embodiment shown in FIGS. 1A to 1F.

In particular, the top chase 130 used in the pressing step which is illustrated in FIG. 1C is removed from the front electronic components 110. Next, As shown in FIG. 2A, a molding top chase 235 including multiple cavities is placed above the top surfaces of the front electronic components 110, and each of the cavities may correspond to one of the front electronic components 110. There exists a gap between the top surfaces of the front electronic components 110 and the bottom surface of the molding top chase 235, such that the front electronic components 110 can be fully encapsulated subsequently. In some embodiments, the molding top chase 235 may be mounted onto an external platform for fixation. Next, a front mold cap 240 is formed between the molding top chase 235 and the front surface of the package substrate 100 using the molding top chase 235 and the bottom chase 121 when the package substrate 100 is loaded between the molding top chase 235 and the bottom chase 121. Further details of the formation of the front mold cap 240 may be similar to those illustrated in the step illustrated in FIG. 1D. In this embodiment, the resulting front mold cap 240 includes multiples stages at its top surface, and each stage is aligned with one of the multiple front electronic components 110 and may cover the top surface of the front electronic component 110, which is the antenna block in this embodiment.

Furthermore, still referring to FIG. 2A, each of the stages may be shaped as a truncated pyramid. Particularly, each of the antenna blocks 110 may be aligned with a truncated pyramid shaped stage. In some other embodiments, the front mold cap 240 above the antenna blocks 110 may have a variety of shapes such as a diamond, hemisphere, semi-elliptical, or lens shape. The shape of the front mold cap 240 may increase transmission and reception area of the antennas 111 included in the corresponding antenna blocks 110. Also, the shape of the front mold cap 240 may optimize refraction, diffraction and reflection characteristics of radiofrequency signals to improve a transmission and reception rate of the antennas 111, thus allowing the electronic package to have an improved antenna performance.

Next, as shown in FIG. 2B, the package substrate 100 and the various components thereon may be removed from the molding top chase 235 and the bottom chase 121. The package substrate 100 may then be flipped over for further attachment of other components on its back surface. In particular, at least one back electronic component 242 are attached onto the back surface of the package substrate 100. The back electronic components 242 may be electrically connected with interconnect wires 101 embedded in the package substrate 100 via a plurality of solder bumps 241. In addition, in the embodiment shown in FIG. 2B, at least one auxiliary back electronic component 245 may be mounted onto the back surface of the package substrate 100 via additional solder bumps 246. The auxiliary back electronic components 245 may include a type of electronic module different from that of the back electronic components 242. For example, the auxiliary back electronic components 245 may include connectors in this embodiment. Next, a molding material is formed on at least part of the back surface of the package substrate 100 to form a back mold cap 250 that encapsulates the at least one back electronic component 242 on the back surface of the package substrate 100. Next, a shielding layer 261 is formed at least outside the top and lateral surfaces of the back mold cap 250, thus forming an electronic package 270. The auxiliary back electronic component 245, which is the connector in the embodiment shown in FIG. 2B, is free from the shielding layer 261 to allow for proper electrical connection between the connector 245 and external devices.

In some embodiments, the electronic package 270 can be applied in any electronic devices which desire front electronic components 110 with uniform structures, improved signal transmission and reception performance, such as in high-sensitive sensors, high performance radio frequency devices or the like.

While the exemplary method for forming an electronic package of the present application is described in conjunction with corresponding figures, it will be understood by those skilled in the art that modifications and adaptations to the method for forming an electronic package may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an electronic package, the method comprising:
providing a package substrate having a front surface and a back surface, wherein multiple sets of conductive pads are formed on the front surface of the package substrate;
forming solder bumps on each set of the multiple sets of conductive pads;
attaching multiple front electronic components onto the front surface of the package substrate via solder bumps, wherein each of the multiple front electronic components is aligned with one set of the multiple sets of conductive pads;
loading the package substrate on a bottom chase with the front surface of the package substrate facing upward;
pressing, with a top chase, the front electronic components against the bottom chase to reshape the solder bumps and horizontally align top surfaces of the front electronic components with each other; and
forming a front mold cap on the front surface of the package substrate to encapsulate the front electronic components.

2. The method of claim 1, wherein the front electronic components comprise antenna blocks with a same height.

3. The method of claim 1, wherein forming a front mold cap on the front surface of the package substrate comprises:
forming the front mold cap with a flat top surface.

4. The method of claim 1, wherein forming a front mold cap on the front surface of the package substrate comprises:
forming the front mold cap having at its top surface multiples stages, wherein each stage is aligned with one of the multiple front electronic components and covers the top surface of the front electronic component.

5. The method of claim 4, wherein forming a front mold cap on the front surface of the package substrate comprises:
forming the front mold cap using a molding top chase and the bottom chase when the package substrate is loaded between the molding top chase and the bottom chase, wherein the molding top chase comprises multiple cavities each corresponding to one of the front electronic components.

6. The method of claim 1, wherein forming a front mold cap on the front surface of the package substrate comprises:
forming the front mold cap using the top chase and the bottom chase when the package substrate is loaded between the top chase and the bottom chase.

7. The method of claim 1, wherein the top chase comprises a base plate and a flexible film, and the flexible film is in contact with the top surfaces of the front electronic components during the pressing step.

8. The method of claim 1, wherein the solder bumps underneath each of the front electronic components are reshaped but not connected with each other after the pressing step.

9. The method of claim 1, wherein after the pressing step and before forming a front mold cap, the method further comprises:
attaching multiple additional front electronic components onto the front surface of the package substrate via additional solder bumps, wherein the multiple additional front electronic components are thicker than the front electronic components attached onto the front surface of the package substrate, and each of the additional front electronic components is aligned with one set of the multiple sets of conductive pads;
loading the package substrate on the bottom chase with the front surface of the package substrate facing upward; and
pressing, with the top chase, the additional front electronic components against the bottom chase to reshape the additional solder bumps and horizontally align top surfaces of the multiple additional front electronic components with each other.

10. The method of claim 1, wherein after forming the front mold cap, the method further comprises:
attaching at least one back electronic component onto the back surface of the package substrate; and
forming a back mold cap on at least part of the back surface of the package substrate to encapsulate the at least one back electronic component.

11. An electronic package which is formed using the method of claim 1.
